(19) United States
(12) Patent Application Publication
(10) Pub. No.: US 2025/0261550 A1
(43) Pub. Date: Aug. 14, 2025

(54) DISPLAY DEVICE

(71) Applicant: Samsung Display Co., Ltd., Yongin-si (KR)

(72) Inventors: Jangun Choi, Yongin-si (KR); Wansang Kim, Yongin-si (KR); Byoungkyoo Park, Yongin-si (KR); Weejoon Jeong, Yongin-si (KR)

(21) Appl. No.: 18/909,653

(22) Filed: Oct. 8, 2024

(30) Foreign Application Priority Data
Feb. 13, 2024 (KR) 10-2024-0020670

(51) Int. Cl. H10K 59/80

(52) U.S. Cl. CPC H10K 59/8794

(57) ABSTRACT

A display device includes: a display panel comprising a substrate and a display element layer on the substrate; and a heat dissipation portion on the display panel, wherein the heat dissipation portion includes: a plurality of pipe portions extending in a first direction, spaced apart from each other in a second direction crossing the first direction, and providing a pipe flow path; a first connection portion connecting two adjacent pipe portions among the plurality of pipe portions to each other and providing a first connection flow path communicating with the pipe flow path; and a working fluid configured to flow through the pipe flow path and the first connection flow path, and wherein each of the plurality of pipe portions includes: a plurality of contact portions including contact surfaces contacting the display panel; and a plurality of spaced portions arranged alternately with the plurality of contact portions.

### CROSS-REFERENCE TO RELATED APPLICATION

The present application claims priority to and the benefit of Korean Patent Application No. 10-2024-0020670, filed on Feb. 13, 2024, in the Korean Intellectual Property Office, the entire disclosure of which is incorporated herein by reference.

### BACKGROUND

### 1. Field

Aspects of one or more embodiments relate to a display device.

### 2. Description of the Related Art

Mobile electronic devices are widely used. As mobile electronic devices, tablet personal computers (PCs) have been widely used in recent years in addition to small electronic devices such as mobile phones.

Such mobile electronic devices include display devices to support various functions, for example, to display visual information, such as images or videos, to users. Recently, as other parts for driving display devices have been miniaturized, the proportion occupied by display devices in electronic devices has gradually increased. Structures capable of being bent from a flat state to have a certain angle are also under development.

The above information disclosed in this Background section is only for enhancement of understanding of the background and therefore the information discussed in this Background section does not necessarily constitute prior art.

### SUMMARY

Aspects of one or more embodiments may enable efficiently dissipating heat generated from a display panel.

However, this is only an example, and the characteristics of embodiments according to the present disclosure are not limited thereto.

Additional aspects will be set forth in part in the description which follows and, in part, will be apparent from the description, or may be learned by practice of the presented embodiments of the disclosure.

According to some embodiments of the present disclosure, a display device includes a display panel including a substrate and a display element layer on the substrate, and a heat dissipation portion on one side of the display panel, wherein the heat dissipation portion includes a plurality of pipe portions extending in a first direction, apart from each other in a second direction crossing the first direction, and providing a pipe flow path, a first connection portion connecting two adjacent pipe portions among the plurality of pipe portions to each other and providing a first connection flow path communicating with the pipe flow path, and a working fluid flowing through the pipe flow path and the first connection flow path, and wherein each of the plurality of pipe portions includes a plurality of contact portions including contact surfaces in contact with the display panel, and a plurality of spaced portions arranged alternately with the plurality of contact portions and apart from the display panel.

According to some embodiments, each of the plurality of pipe portions may include a pulsating heat pipe (PHP).

According to some embodiments, at least a portion of the working fluid may evaporate at the plurality of contact portions and may condense at the plurality of spaced portions.

According to some embodiments, the working fluid may circulate through the plurality of pipe portions.

According to some embodiments, when viewed from a front, each of the plurality of pipe portions may have a serpentine shape.

According to some embodiments, the plurality of pipe portions may be arranged side-by-side.

According to some embodiments, at least a portion of the first connection portion may be in contact with the display panel.

According to some embodiments, the heat dissipation portion may further include a second connection portion connecting two most spaced pipe portions among the plurality of pipe portions to each other and providing a second connection flow path communicating with the pipe flow path.

According to some embodiments, the second connection portion may extend in the second direction.

According to some embodiments, the display panel may include a first surface on which an image is provided and a second surface opposite to the first surface, and the heat dissipation portion may be on the second surface of the display panel.

According to some embodiments of the present disclosure, a display device includes a display panel including a substrate and a display element layer on the substrate, and a heat dissipation portion on one side of the display panel, wherein the heat dissipation portion includes a first pipe portion extending in a first direction and providing a first pipe flow path, a second pipe portion extending in the first direction, providing a second pipe flow path, and apart from the first pipe portion in a second direction crossing the first direction, a first connection portion connecting the first pipe portion to the second pipe portion and providing a first connection flow path communicating with each of the first pipe flow path and the second pipe flow path, and a working fluid flowing through the first pipe flow path, the second pipe flow path, and the first connection flow path, and wherein each of the first pipe portion and the second pipe portion includes a plurality of contact portions including contact surfaces in contact with the display panel, and a plurality of spaced portions arranged alternately with the plurality of contact portions and apart from the display panel.

According to some embodiments, each of the first pipe portion and the second pipe portion may include a pulsating heat pipe (PHP).

According to some embodiments, at least a portion of the working fluid may evaporate at the plurality of contact portions and may condense at the plurality of spaced portions.

According to some embodiments, the working fluid may circulate through the first pipe portion and the second pipe portion.

According to some embodiments, when viewed from a front, each of the first pipe portion and the second pipe portion may have a serpentine shape.

According to some embodiments, the first pipe portion and the second pipe portion may be arranged side-by-side.

According to some embodiments, at least a portion of the first connection portion may be in contact with the display panel.

According to some embodiments, the heat dissipation portion may further include a third pipe portion extending in the first direction, providing a third pipe flow path communicating with the second pipe flow path, and apart from the second pipe portion in the second direction, and a second connection portion connecting the first pipe portion to the third pipe portion and providing a second connection flow path communicating with each of the first pipe flow path and the third pipe flow path.

According to some embodiments, the second connection portion may extend in the second direction.

According to some embodiments, the display panel may include a first surface on which an image is provided and a second surface opposite to the first surface, and the heat dissipation portion may be on the second surface of the display panel.

Other aspects, features, and characteristics of embodiments according to the present disclosure will become better understood through the accompanying drawings, the appended claims, and the detailed description.

### BRIEF DESCRIPTION OF THE DRAWINGS

The above and other aspects, features, and characteristics of certain embodiments of the present disclosure will be more apparent from the following description taken in conjunction with the accompanying drawings, in which:

FIG. 1 is a plan view schematically illustrating a display device according to some embodiments;

FIG. 2 is a front view schematically illustrating the display device according to some embodiments;

FIG. 3 is a perspective view schematically illustrating the display device according to some embodiments;

FIG. 4 is a cross-sectional view schematically illustrating a plurality of pipe portions, a first connection portion, and a second connection portion, according to some embodiments;

FIG. 5 is a front view schematically illustrating the display device according to some embodiments;

FIG. 6 is a cross-sectional view schematically illustrating the display panel according to some embodiments;

FIG. 7 is an equivalent circuit diagram of a pixel of a display panel, according to some embodiments; and

FIG. 8 is an equivalent circuit diagram of a pixel of a display panel, according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the present description allows for various changes and numerous embodiments, certain embodiments will be illustrated in the drawings and described in detail in the written description. Effects and features of the disclosure, and methods of achieving them will be clarified with reference to embodiments described below in detail with reference to the drawings. However, embodiments according to the present disclosure are not limited to the following description may be embodied in various forms.

Hereinafter, embodiments will be described in detail with reference to the accompanying drawings. When describing embodiments with reference to the accompanying drawings, the same or corresponding elements are denoted by the same reference numerals, and redundant descriptions thereof are omitted.

It will be understood that although the terms “first,” “second,” etc. may be used herein to describe various elements, these elements should not be limited by these terms. These terms are only used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

It will be further understood that, when a layer, region, or element is referred to as being “on” another layer, region, or element, this may be directly on the other layer, region, or element, but also intervening layers, regions, or elements may be present therebetween.

Also, sizes of elements in the drawings may be exaggerated or reduced for convenience of explanation. For example, because sizes and thicknesses of elements in the drawings are arbitrarily illustrated for convenience of explanation, embodiments according to the present disclosure are not limited thereto.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

When a certain embodiment is implemented differently, a specific process sequence may be performed differently from a sequence described herein. For example, two consecutively described processes may be performed substantially at the same time or performed in an order opposite to the stated order.

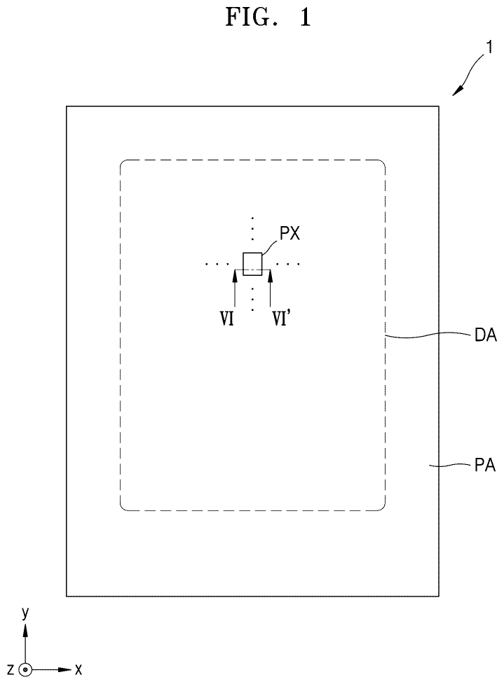

FIG. 1 is a plan view schematically illustrating a display device 1 according to some embodiments.

Referring of FIG. 1, the display device 1 manufactured according to some embodiments may include a display area DA and a peripheral area PA outside (e.g., in a periphery or outside a footprint of) the display area DA. The display device 1 may display images through an array of a plurality of pixels PX two-dimensionally arranged in the display area DA.

The peripheral area PA is an area at which images are not provided and may completely or partially surround the display area DA. A driver or the like configured to provide electrical signals or power to pixel circuits respectively corresponding to the pixels PX may be arranged in the peripheral area PA. A pad, which is an area to which an electronic element or a printed circuit board may be electrically connected, may be arranged in the peripheral area PA.

Hereinafter, embodiments according to the present disclosure are described in the context of display device 1 including an organic light-emitting diode as a light-emitting element, but the display device 1 according to embodiments of the present disclosure is not limited thereto. According to some embodiments, the display device 1 may be a light-emitting display including an inorganic light-emitting diode (LED), that is, an inorganic light-emitting display. The inorganic LED may include a PN junction diode including inorganic semiconductor-based materials. When a voltage is applied to the PN junction diode in a forward direction, holes and electrons may be injected and recombined to generate energy, and the energy may be converted into light energy to emit light of a certain color. The inorganic LED may have a width of several to hundreds of micrometers. According to some embodiments, the inorganic LED may be referred to as a micro LED. According to some embodiments, the display device 1 may be a quantum dot light-emitting display.

The display device 1 may be used as display screens of portable electronic devices, such as mobile phones, smartphones, tablet personal computers (PCs), mobile communication terminals, electronic organizers, e-books, portable multimedia players (PMPs), navigation systems, and ultra mobile PCs (UMPCs). Also, the display device 1 may be used as display screens of various products, such as televisions, laptops, monitors, billboards, and Internet of things (IoT) devices. The display device 1 according to some embodiments may also be used in wearable devices, such as smart watches, watch phones, glasses-type displays, and head mounted displays (HMDs). The display device 1 according to some embodiments may also be used in dashboards of automobiles, center information displays (CIDs) on the center fascia or dashboards of automobiles, room mirror displays replacing side mirrors of automobiles, and display screens on the rear sides of front seats to serve as entertainment devices for backseat passengers of automobiles.

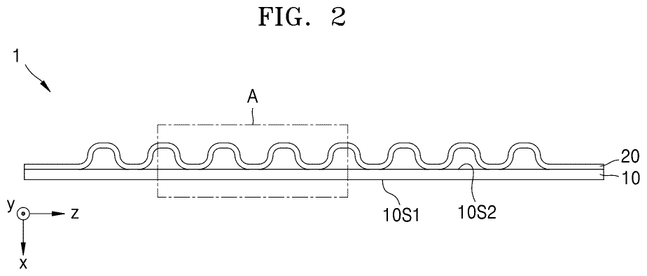

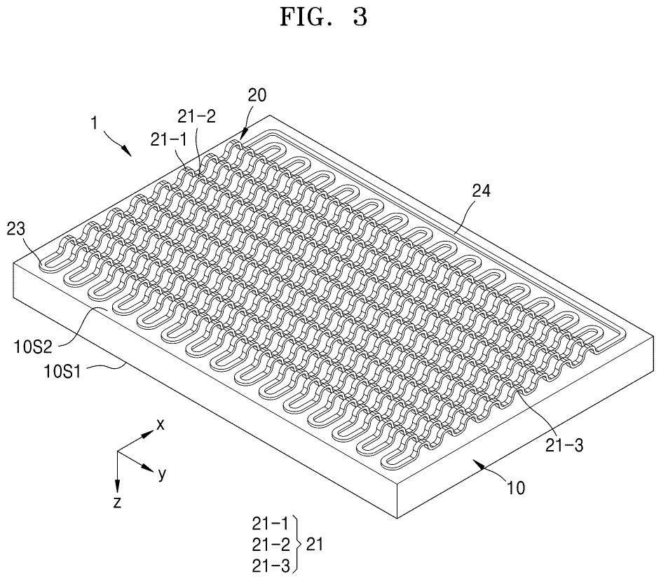

FIG. 2 is a front view schematically illustrating the display device 1 according to some embodiments, and FIG. 3 is a perspective view schematically illustrating the display device 1 according to some embodiments.

Referring to FIGS. 2 and 3, the display device 1 may include a display panel 10 and a heat dissipation portion 20.

The display panel 10 may include a first surface 10S1 at which images are displayed, and a second surface 10S2 opposite to the first surface 10S1. For example, the display panel 10 may be provided in the form of a thin plate. For example, in a plan view, the display panel 10 may have a rectangular shape, as illustrated in FIG. 3. However, this is only an example, and the shape of the display panel 10 is not limited thereto. While the display panel 10 displays images, heat may be generated in the display panel 10.

The heat dissipation portion 20 may be arranged on one side of the display panel 10 and may dissipate heat from the display panel 10. At least a portion of the heat emitted from the display panel 10 may be transferred to the heat dissipation portion 20. The heat dissipation portion 20 may externally emit at least a portion of heat generated in the display panel 10. The second surface 10S2 of the display panel 10 may include a flat surface, and the heat dissipation portion 20 may be located on the second surface 10S2 of the display panel 10.

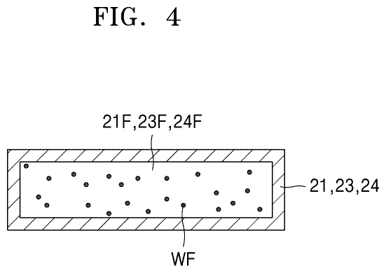

FIG. 4 is a cross-sectional view schematically illustrating a plurality of pipe portions 21, a first connection portion 23, and a second connection portion 24, according to some embodiments.

Referring to FIGS. 3 and 4, the heat dissipation portion 20 may include the pipe portions 21, the first connection portion 23, the second connection portion 24, and a working fluid WF.

Each of the pipe portions 21 may extend in a first direction (e.g., +x and/or −x direction) and may provide a pipe flow path 21F. The pipe flow path 21F may be defined as a space formed inside each of the pipe portions 21. The pipe portions 21 may be apart from each other in a second direction (e.g., +y and/or −y direction). The second direction (e.g., the +y and/or −y direction) may be a direction crossing the first direction (e.g., the +x and/or −x direction). For example, the pipe portions 21 may be arranged side-by-side.

As illustrated in FIG. 4, the cross-sectional shape of the pipe flow path 21F may correspond to the cross-sectional shape of the pipe portion 21. For example, the cross-sectional shape of each of the pipe portions 21 may be rectangular, and the cross-sectional shape of the pipe flow path 21F may also be rectangular. However, this is only an example, and the shapes of the pipe portions 21 and the pipe flow path 21F are not limited thereto. The working fluid WF may be received in the pipe flow path 21F.

For example, the pipe portions 21 may include a first pipe portion 21-1, a second pipe portion 21-2, and a third pipe portion 21-3. The first pipe portion 21-1 may extend in the first direction (e.g., the +x and/or −x direction) and may provide a first pipe flow path 21F. The second pipe portion 21-2 may extend in the first direction (e.g., the +x and/or −x direction), may provide a second pipe flow path 21F, and may be apart from the first pipe portion 21-1 in the second direction (e.g., the +y direction). The third pipe portion 21-3 may extend in the first direction (e.g., the +x and/or −x direction), may provide a third pipe flow path 21F, and may be apart from the second pipe portion 21-2 in the second direction (e.g., the +y direction). For example, the first pipe portion 21-1, the second pipe portion 21-2, and the third pipe portion 21-3 may be arranged side-by-side. The first pipe flow path 21F, the second pipe flow path 21F, and the third pipe flow path 21F may communicate with each other.

Among the pipe portions 21, the first pipe portion 21-1 and the second pipe portion 21-2 may be arranged closest to each other, and the first pipe portion 21-1 and the third pipe portion 21-3 may be arranged farthest from each other. A plurality of pipe portions 21 may be additionally arranged between the second pipe portion 21-2 and the third pipe portion 21-3.

The first connection portion 23 may connect two adjacent pipe portions 21 to each other and may provide a first connection flow path 23F communicating with the pipe flow path 21F. The first connection flow path 23F may be defined as a space formed inside each of the first connection portions 23.

As illustrated in FIG. 4, the cross-sectional shape of the first connection flow path 23F may correspond to the cross-sectional shape of the first connection portion 23. For example, the cross-sectional shape of each of the first connection portions 23 may be rectangular, and the cross-sectional shape of the first connection flow path 23F may also be rectangular. However, this is only an example, and the shapes of the first connection portions 23 and the first connection flow path 23F are not limited thereto. The working fluid WF may be received in the first connection flow path 23F.

The number of first connection portions 23 may be one less than the number of pipe portions 21. For example, when two pipe portions 21 are provided, one first connection portion 23 may be provided. Alternatively, when three pipe portions 21 are provided, two first connection portions 23 may be provided. Alternatively, as illustrated in FIG. 3, when 30 pipe portions 21 are provided, 29 first connection portions 23 may be provided.

When the first connection portions 23 are provided in plurality, the first connection portions 23 may be arranged in a zigzag shape. One of the first connection portions 23 may connect one end of one pipe portion 21 to one end of another pipe portions 21. Alternatively, another one of the first connection portions 23 may connect the other end of one pipe portion 21 to one end of further another pipe portions 21. For example, the first connection portion 23 may connect the first pipe portion 21-1 to the second pipe portion 21-2, and the first connection flow path 23F may communicate with each of the first pipe flow path 21F and the second pipe flow path 21F.

The second connection portion 24 may connect two most spaced pipe portions 21 to each other and may provide a second connection flow path 24F communicating with the pipe flow path 21F. The second connection flow path 24F may be defined as a space formed inside each of the second connection portions 24.

As illustrated in FIG. 4, the cross-sectional shape of the second connection flow path 24F may correspond to the cross-sectional shape of the second connection portion 24. For example, the cross-sectional shape of each of the second connection portions 24 may be rectangular, and the cross-sectional shape of the second connection flow path 24F may also be rectangular. However, this is only an example, and the shapes of the second connection portions 24 and the second connection flow path 24F are not limited thereto.

For example, the second connection portion 24 may extend in the second direction (e.g., the +y and/or −y direction) and may connect the first pipe portion 21-1 to the third pipe portion 21-3. The second connection flow path 24F may communicate with each of the first pipe flow path 21F and the third pipe flow path 21F. The working fluid WF may be received in the second connection flow path 24F.

In such a structure, the first pipe portions 21-1, the first connection portion 23, and the second connection portion 24 may provide a closed flow path. The working fluid WF may alternately flow through the pipe portions 21 and the first connection portion 23 and then return to one of the pipe portions 21 through the second connection portion 24. The working fluid WF may circulate through the pipe portions 21. That is, the working fluid WF may circulate while flowing through the first pipe flow path 21F, the second pipe flow path 21F, the third pipe flow path 21F, the first connection flow path 23F, and the second connection flow path 24F.

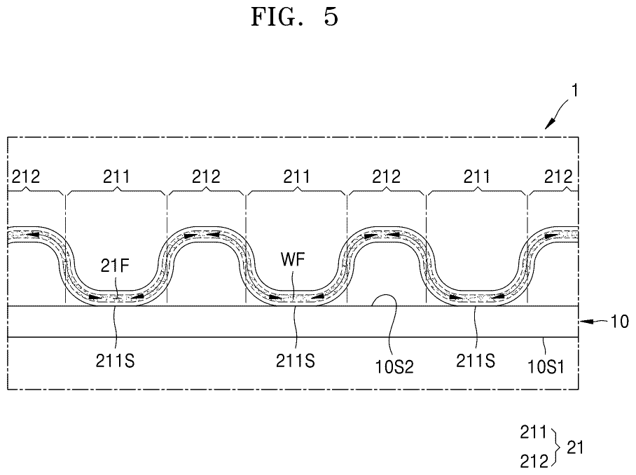

FIG. 5 is a front view schematically illustrating the display device 1 according to some embodiments. For example, FIG. 5 is an enlarged view of a portion A of FIG. 2.

Referring to FIGS. 3 to 5, each of the pipe portions 21 may include a plurality of contact portions 211 and a plurality of spaced portions 212. For example, each of the first pipe portion 21-1, the second pipe portion 21-2, and the third pipe portion 21-3 may include the contact portions 211 and the spaced portions 212.

Each of the contact portions 211 may include a contact surface 211S in contact with the display panel 10. The contact surface 211S of each of the contact portions 211 may be in contact with a second surface 10S2 of the display panel 10. Each of the spaced portions 212 may be apart from the display panel 10. The spaced portions 212 may be arranged alternately with the contact portions 211.

The contact portions 211 and the spaced portions 212 may be connected to each other. Accordingly, the flow paths formed inside the contact portions 211 and the flow paths formed inside the spaced portions 212 may communicate with each other. Two adjacent spaced portions 212 may be connected to one contact portion 211, and two adjacent contact portions 211 may be connected to one spaced portion 212.

In such a structure, when viewed from the front (for example, when viewed from the +y direction) as illustrated in FIG. 5, each of the pipe portions 21 may have a serpentine shape. For example, when viewed from the front (for example, when viewed from the +y direction), each of the first pipe portion 21-1, the second pipe portion 21-2, and the third pipe portion 21-3 may have a serpentine shape.

At least a portion of the working fluid WF may evaporate in the contact portion 211 and condense in the spaced portion 212. That is, each of the pipe portions 21 may be provided as a pulsating heat pipe (PHP). For example, each of the first pipe portion 21-1, the second pipe portion 21-2, and the third pipe portion 21-3 may be provided as a PHP.

Heat emitted from the display panel 10 may be transferred to the contact portion 211 through the second surface 10S2 of the display panel 10. Accordingly, the working fluid WF received in the pipe flow path 21F of the contact portion 211 may evaporate and expand. The evaporation of the working fluid WF may result in slug-shaped bubbles. In this process, the expanding working fluid WF in the contact portion 211 may flow to the spaced portion 212.

Because the spaced portion 212 is apart from the display panel 10, the temperature of the spaced portion 212 may be lower than the temperature of the contact portion 211. Accordingly, the working fluid WF received in the pipe flow path 21F of the spaced portion 212 may condense. Accordingly, the condensing working fluid WF in the spaced portion 212 may flow to the contact portion 211.

For example, the working fluid WF may include at least one of R-245fa, R-1233zd, diethyl ether, ethanol, acetone, or distilled Water. However, this is only an example, and a material of the working fluid WF is not limited thereto.

Because the contact portions 211 and the spaced portions 212 are alternately arranged, a driving force of the working fluid WF received in the pipe flow path 21F may increase. Accordingly, the working fluid WF may actively vibrate and/or circulate in the pipe flow path 21F. Accordingly, natural convection may occur on the surfaces of the pipe portions 21. In addition, the structure of the pipe portions 21 may increase the surface area of the pipe portions 21. Accordingly, the heat dissipation efficiency of the display panel 10 may be relatively improved without other heat dissipation devices such as separate fans.

Referring again to FIG. 3, at least a portion of the first connection portion 23 may be in contact with the display panel 10. In addition, at least a portion of the second connection portion 24 may be in contact with the display panel 10. For example, as illustrated in FIG. 3, the lower surface of each of the first connection portion 23 and the second connection portion 24 may be in contact with the second surface 10S2 of the display panel 10. However, this is only an example. Unlike as illustrated in FIG. 3, each of the first connection portion 23 and the second connection portion 24 may have a serpentine shape when viewed from one direction, like the pipe portions 21.

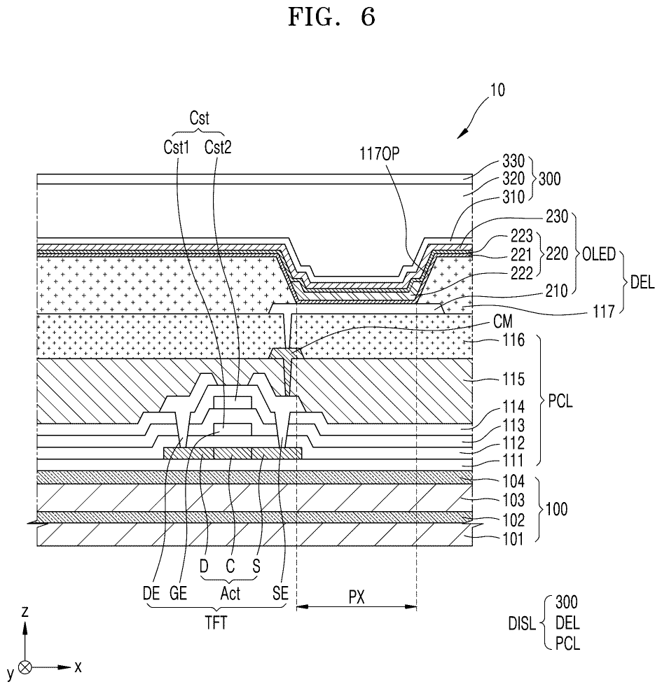

FIG. 6 is a cross-sectional view schematically illustrating the display panel 10 according to some embodiments and may correspond to the cross-section of the display device 1 taken along the line VI-VI′ of FIG. 1.

Referring to FIG. 6, the display panel 10 may include a substrate 100 and a display layer DISL. For example, the display layer DISL may include a structure in which a pixel circuit layer PCL, a display element layer DEL, and an encapsulation layer 300 are stacked in this stated order.

The substrate 100 may have a multilayer structure including an inorganic layer and a base layer including polymer resin. For example, the substrate 100 may include a base layer including polymer resin and a barrier layer of an inorganic insulating layer. For example, the substrate 100 may include a first base layer 101, a first barrier layer 102, a second base layer 103, and a second barrier layer 104, which are sequentially stacked in this stated order. For example, the first base layer 101 and the second base layer 103 may each include polyimide (PI), polyethersulfone (PES), polyarylate, polyetherimide (PEI), polyethylene naphthalate (PEN), polyethylene terephthalate (PET), polyphenylene sulfide (PPS), polycarbonate (PC), cellulose triacetate (TAC), and/or cellulose acetate propionate (CAP). The first barrier layer 102 and the second barrier layer 104 may each include an inorganic insulating material, such as silicon oxide, silicon oxynitride, and/or silicon nitride. The substrate 100 may be flexible.

The pixel circuit layer PCL may be located on the substrate 100. FIG. 6 illustrates that the pixel circuit layer PCL includes a thin-film transistor TFT, and a buffer layer 111, a first gate insulating layer 112, a second gate insulating layer 113, an interlayer insulating layer 114, a first planarization insulating layer 115, and a second planarization insulating layer 116, which are located below and/or above elements of the thin-film transistor TFT.

The buffer layer 111 may relatively reduce or prevent infiltration of foreign material, moisture, or ambient air from below the substrate 100 and may provide a flat surface on the substrate 100. The buffer layer 111 may include an inorganic material, such as silicon oxide, silicon oxynitride, or silicon nitride, and may include a single-layer or a multilayer structure including the inorganic material described above.

The thin-film transistor TFT on the buffer layer 111 may include a semiconductor layer Act, and the semiconductor layer Act may include polysilicon (poly-Si). Alternatively, the semiconductor layer Act may include amorphous silicon (a-Si), an oxide semiconductor, or an organic semiconductor. The semiconductor layer Act may include a channel region C, and a drain region D and a source region S respectively on both sides of the channel region C. A gate electrode GE may overlap the channel region C.

The gate electrode GE may include a low-resistance metal material. The gate electrode GE may include a conductive material including molybdenum (Mo), aluminum (AI), copper (Cu), titanium (Ti), and the like, and may include a single layer or layers including the conductive material described above.

The first gate insulating layer 112 between the semiconductor layer Act and the gate electrode GE may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂.

The second gate insulating layer 113 may be provided to cover the gate electrode GE. Similar to the first gate insulating layer 112, the second gate insulating layer 113 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂.

An upper electrode Cst2 of a storage capacitor Cst may be located on the second gate insulating layer 113. The upper electrode Cst2 may overlap the gate electrode GE therebelow. In this case, the gate electrode GE and the upper electrode Cst2 overlapping each other with the second gate insulating layer 113 therebetween may constitute the storage capacitor Cst. That is, the gate electrode GE may serve as a lower electrode Cst1 of the storage capacitor Cst.

As described above, the storage capacitor Cst and the thin-film transistor TFT may overlap each other. According to some embodiments, the storage capacitor Cst may not overlap the thin-film transistor TFT.

The upper electrode Cst2 may include aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or layers including the material described above.

The interlayer insulating layer 114 may cover the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be ZnO and/or ZnO₂. The interlayer insulating layer 114 may include a single layer or layers including the inorganic insulating material described above.

A drain electrode DE and a source electrode SE may be located on the interlayer insulating layer 114. The drain electrode DE and the source electrode SE may be respectively connected to the drain region D and the source region S through contact holes formed in the insulating layers therebelow. The drain electrode DE and the source electrode SE may include a material having good conductivity. The drain electrode DE and the source electrode SE may each include a conductive material including molybdenum (Mo), aluminum (AI), copper (Cu), titanium (Ti), and the like, and may each include a single layer or layers including the conductive material described above. According to some embodiments, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating material selected from general-purpose polymer, such as polymethylmethacrylate (PMMA) or polystyrene (PS), polymer derivatives having a phenolic group, acrylic polymer, imide-based polymer, aryl ether-based polymer, amide-based polymer, fluorine-based polymer, p-xylene-based polymer, vinyl alcohol-based polymer, and any blend thereof.

The second planarization insulating layer 116 may be located on the first planarization insulating layer 115. The second planarization insulating layer 116 may include the same material as the material of the first planarization insulating layer 115 and may include an organic insulating material selected from general-purpose polymer, such as PMMA or PS, polymer derivatives having a phenolic group, acrylic polymer, imide-based polymer, aryl ether-based polymer, amide-based polymer, fluorine-based polymer, p-xylene-based polymer, vinyl alcohol-based polymer, and any blend thereof.

The display element layer DEL may be located on the pixel circuit layer PCL having the above-described structure. The display element layer DEL may include an organic light-emitting diode OLED as a display element (i.e., a light-emitting element), and the organic light-emitting diode OLED may include a structure in which a pixel electrode 210, an intermediate layer 220, and a common electrode 230 are stacked. The organic light-emitting diode OLED may be configured to emit, for example, red light, green light, or blue light, or may be configured to emit, for example, red light, green light, blue light, or white light. The organic light-emitting diode OLED may be configured to emit light through an emission area, and the emission area may be defined as a pixel PX.

The pixel electrode 210 of the organic light-emitting diode OLED may be electrically connected to the thin-film transistor TFT through contact holes formed in the second planarization insulating layer 116 and the first planarization insulating layer 115 and a contact metal CM located on the first planarization insulating layer 115.

The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the pixel electrode 210 may include a reflective layer including silver (Ag), magnesium (Mg), aluminum (AI), platinum (Pt), palladium (Pd), gold (Au), nickel (Ni), neodymium (Nd), iridium (Ir), chromium (Cr), or any compound thereof. According to some embodiments, the pixel electrode 210 may further include a layer including ITO, IZO, ZnO, or In₂O₃ above and/or below the reflective layer.

A bank layer 117 having an opening 117OP exposing the central portion of the pixel electrode 210 may be located on the pixel electrode 210. The bank layer 117 may include an organic insulating material and/or an inorganic insulating material. The opening 117OP may define an emission area of light emitted from the organic light-emitting diode OLED. For example, the size and/or width of the opening 117OP may correspond to the size and/or width of the emission area. Accordingly, the size and/or width of the pixel-pixel PX may depend on the size and/or width of the opening 117OP of the bank layer 117 corresponding thereto.

The intermediate layer 220 may include an emission layer 222 corresponding to the pixel electrode 210. The emission layer 222 may include a high molecular weight organic material or a low molecular weight organic material that emits light of a certain color. Alternatively, the emission layer 222 may include an inorganic light-emitting material or quantum dots.

According to some embodiments, the intermediate layer 220 may include a first functional layer 221 and a second functional layer 223 respectively located below and above the emission layer 222. For example, the first functional layer 221 may include a hole transport layer (HTL), or may include an HTL and a hole injection layer (HIL). The second functional layer 223 may be located above the emission layer 222 and may include an electron transport layer (ETL) and/or an electron injection layer (EIL). The first functional layer 221 and/or the second functional layer 223 may be a common layer completely covering the substrate 100, like the common electrode 230 to be described later.

The common electrode 230 may be located on the pixel electrode 210 and may overlap the pixel electrode 210. The common electrode 230 may include a conductive material having a low work function. For example, the common electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the common electrode 230 may further include a layer including ITO, IZO, ZnO, or In₂O₃ on the (semi) transparent layer including the material described above. The common electrode 230 may be integrally formed to completely cover the substrate 100.

The encapsulation layer 300 may be located on the display element layer DEL and may cover the display element layer DEL. The encapsulation layer 300 may include at least one inorganic encapsulation layer and at least one organic encapsulation layer. According to some embodiments, FIG. 6 illustrates that the encapsulation layer 300 includes a first inorganic encapsulation layer 310, an organic encapsulation layer 320, and a second inorganic encapsulation layer 330, which are sequentially stacked in this stated order.

The first inorganic encapsulation layer 310 and the second inorganic encapsulation layer 330 may each include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, polyimide, polyethylene, and the like. According to some embodiments, the organic encapsulation layer 320 may include acrylate. The organic encapsulation layer 320 may be formed by curing a monomer or applying a polymer. The organic encapsulation layer 320 may be transparent.

According to some embodiments, a touch sensor layer may be located on the encapsulation layer 300, and an optical functional layer may be located on the touch sensor layer. The touch sensor layer may be configured to obtain coordinate information according to an external input, for example, a touch event. The optical functional layer may relatively reduce the reflectance of light (external light) incident from the outside toward the display device, and/or may relatively improve the color purity of light emitted from the display device. According to some embodiments, the optical functional layer may include a retarder and/or a polarizer. The retarder may be a film-type retarder or a liquid crystal coating-type retarder and may include a N/2 retarder and/or a N/4 retarder. The polarizer may be a film-type polarizer or a liquid crystal coating-type polarizer. The film-type retarder or polarizer may include a stretched synthetic resin film, and the liquid crystal coating-type retarder or polarizer may include liquid crystals arranged in a certain array. Each of the retarder and the polarizer may further include a protection film.

An adhesive member may be arranged between the touch sensor layer and the optical function layer. As the adhesive member, any general adhesive member known in the art may be employed without limitation. The adhesive member may be a pressure sensitive adhesive (PSA).

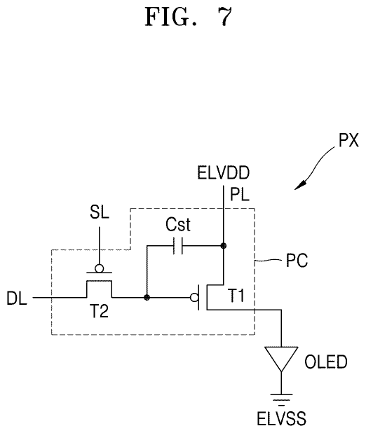

FIG. 7 is an equivalent circuit diagram of the pixel PX of the display panel 10, according to some embodiments.

Referring to FIG. 7, the pixel PX may include a pixel circuit PC and a display element connected to the pixel circuit PC. For example, the display element may be an organic light-emitting diode OLED. The pixel circuit PC may include a first thin-film transistor T1, a second thin-film transistor T2, and a storage capacitor Cst. The pixel PX may emit, for example, red light, green light, blue light, or white light from the organic light-emitting diode OLED.

The second thin-film transistor T2, which acts as a switching thin-film transistor, may be connected to a scan line SL and a data line DL and may be configured to transmit, to the first thin-film transistor T1, a data voltage input from the data line DL in response to a switching voltage input from the scan line SL. The storage capacitor Cst may be connected to the second thin-film transistor T2 and a driving voltage line PL and may be configured to store a voltage corresponding to a difference between a voltage received from the second thin-film transistor T2 and a first power supply voltage ELVDD supplied to the driving voltage line PL.

The first thin-film transistor T1, which acts as a driving thin-film transistor, may be connected to the driving voltage line PL and the storage capacitor Cst and may be configured to control a driving current flowing from the driving voltage line PL to the organic light-emitting diode OLED according to a voltage value stored in the storage capacitor Cst. The organic light-emitting diode OLED may be configured to emit light with a certain luminance according to the driving current. An opposite electrode (e.g., a cathode) of the organic light-emitting diode OLED may be configured to receive a second power supply voltage ELVSS.

FIG. 7 illustrates that the pixel circuit PC includes two thin-film transistors and one storage capacitor, but embodiments according to the present disclosure are not limited thereto. The number of thin-film transistors and the number of storage capacitors may be variously changed according to the design of the pixel circuit PC. For example, the pixel circuit PC may further include four or more thin-film transistors. According to some embodiments, the pixel circuit PC may include additional components or fewer components without departing from the spirit and scope of embodiments according to the present disclosure.

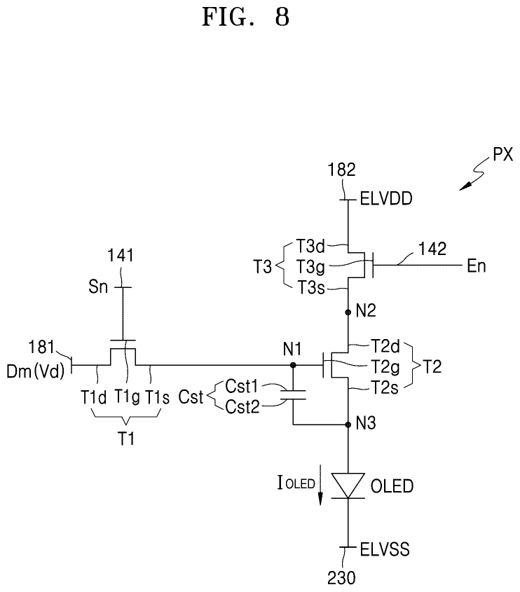

FIG. 8 is an equivalent circuit diagram of the pixel PX of the display panel 10, according to some embodiments.

Referring to FIG. 8, the pixel PX may include a pixel circuit and an organic light-emitting diode OLED. The pixel circuit may include first to third thin-film transistors T1, T2, and T3 and a storage capacitor Cst. The first to third thin-film transistors T1, T2, and T3 may be respectively referred to as a switching transistor T1, a driving transistor T2, and a control transistor T3. A gate T2g of the driving transistor T2 is defined as a first node N1, a drain T2d of the driving transistor T2 is defined as a second node N2, and a source T2s of the driving transistor T2 is defined as a third node N3. FIG. 8 illustrates that the first to third thin-film transistors T1, T2, and T3 are n-type metal-oxide semiconductor (MOS) transistors, but this is only an example. The disclosure may also be applied to a pixel including thin-film transistors implemented as p-type MOS transistors.

A first gate line 141 may be configured to transmit a scan signal Sn to a gate T1g of the switching transistor T1, and a second gate line 142 may be configured to transmit a control signal En to a gate T3g of the control transistor T3. A data line 181 may be configured to transmit a data signal Dm having a data voltage Vd to a drain T1d of the switching transistor T1, and a power line 182 may be configured to transmit a first driving voltage ELVDD to a drain T3d of the control transistor T3. A common electrode 230 may be configured to apply a second driving voltage ELVSS to a cathode of the organic light-emitting diode OLED.

The switching transistor T1 may have the gate T1g connected to the first gate line 141, the drain T1d connected to the data line 181, and a source T1s connected to the first node N1. The switching transistor T1 may be configured to transmit the data signal Dm to the first node N1 in response to the scan signal Sn. The data voltage Vd of the data signal Dm may be applied to a first capacitor electrode Cst1 and stored in a storage capacitor Cst.

The driving transistor T2 may have the gate T2g connected to the first node N1, the drain T2d connected to the second node N2, and the source T2s connected to the third node N3. The driving transistor T2 may be configured to generate a driving current I_{OLED} corresponding to a voltage obtained by subtracting a threshold voltage (Vth) of the driving transistor T2 from a voltage across the storage capacitor Cst connected between the gate T2g and the source T2s of the driving transistor T2, and output the driving current I_{OLED} to the organic light-emitting diode OLED.

The control transistor T3 may have the gate T3g connected to the second gate line 142, the drain T3d connected to the power line 182, and a source T3s connected to the second node N2. When the control transistor T3 is turned on in response to the control signal En, a current path passing through the driving transistor T2 may be formed between the power line 182 and the common electrode 230.

The storage capacitor Cst may have the first capacitor electrode Cst1 connected to the first node N1 and a second capacitor electrode Cst2 connected to the third node N3. The storage capacitor Cst may be configured to store the data voltage Vd transmitted through the switching transistor T1.

The organic light-emitting diode OLED may have an anode connected to the third node N3 and the cathode connected to the common electrode 230. The organic light-emitting diode OLED may be configured to emit light according to the driving current I_{OLED} output from the driving transistor T2.

Aspects of an operation of the pixel PX according to some embodiments is described in more detail below.

When the control signal En of a low level is applied to the second gate line 142, the control transistor T3 may be turned off, the current path passing through the driving transistor T2 may be blocked, and the organic light-emitting diode OLED may not emit light. The switching transistor T1 may be configured to transmit the data signal Dm to the first node N1 in response to the scan signal Sn of a high level. The storage capacitor Cst may be configured to store the data voltage Vd of the data signal Dm. Because the storage capacitor Cst is connected between the gate T2g and the source T2s of the driving transistor T2, the driving transistor T2 may be configured to generate the driving current I_{OLED} corresponding to a voltage obtained by subtracting the threshold voltage of the driving transistor T2 from the voltage stored in the storage capacitor Cst.

When the control signal En of a high level is applied to the second gate line 142, the control transistor T3 may be turned on and the current path passing through the driving transistor T2 may be formed. The driving current I_{OLED} output from the driving transistor T2 may flow through the organic light-emitting diode OLED, and the organic light-emitting diode OLED may be configured to emit light with a luminance corresponding to the driving current I_{OLED}.

Although various components are illustrated in the pixel PX, embodiments according to the present disclosure are not limited thereto. For example, according to some embodiments, the pixel PX may include additional components or fewer components, or the arrangement of components may vary without departing from the spirit and scope of embodiments according to the present disclosure.

According to one or more embodiments, because heat generated from the display panel may be dissipated utilizing a structure according to embodiments of the present disclosure, the manufacturing cost of the display device may be relatively reduced and the durability of the display device may be relatively improved.

The characteristics of embodiments according to the present disclosure are not limited to those described above, and other characteristics that are not mentioned herein will be clearly understood from the description of the claims by those of ordinary skill in the art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display device comprising:
a display panel comprising a substrate and a display element layer on the substrate; and
a heat dissipation portion on one side of the display panel,
wherein the heat dissipation portion comprises:
a plurality of pipe portions extending in a first direction, spaced apart from each other in a second direction crossing the first direction, and providing a pipe flow path;
a first connection portion connecting two adjacent pipe portions among the plurality of pipe portions to each other and providing a first connection flow path communicating with the pipe flow path; and
a working fluid configured to flow through the pipe flow path and the first connection flow path, and
wherein each of the plurality of pipe portions comprises:
a plurality of contact portions including contact surfaces contacting the display panel; and
a plurality of spaced portions arranged alternately with the plurality of contact portions and spaced apart from the display panel.

2. The display device of claim 1, wherein each of the plurality of pipe portions comprises a pulsating heat pipe (PHP).

3. The display device of claim 1, wherein the plurality of contact portions are configured to evaporate at least a portion of the working fluid and the plurality of spaced portions are configured to condense the portion of the working fluid.

4. The display device of claim 1, wherein the plurality of pipe portions are configured to circulate the working fluid therethrough.

5. The display device of claim 1, wherein, in a front view, each of the plurality of pipe portions has a serpentine shape.

6. The display device of claim 1, wherein the plurality of pipe portions are arranged side-by-side.

7. The display device of claim 1, wherein at least a portion of the first connection portion contacts the display panel.

8. The display device of claim 1, wherein the heat dissipation portion further comprises a second connection portion connecting two most spaced apart pipe portions among the plurality of pipe portions to each other and providing a second connection flow path communicating with the pipe flow path.

9. The display device of claim 8, wherein the second connection portion extends in the second direction.

10. The display device of claim 1, wherein the display panel includes a first surface configured to display an image and a second surface opposite to the first surface, and
the heat dissipation portion is on the second surface of the display panel.

11. A display device comprising:
a display panel comprising a substrate and a display element layer on the substrate; and
a heat dissipation portion on one side of the display panel,
wherein the heat dissipation portion comprises:
a first pipe portion extending in a first direction and providing a first pipe flow path;
a second pipe portion extending in the first direction, providing a second pipe flow path, and spaced apart from the first pipe portion in a second direction crossing the first direction;
a first connection portion connecting the first pipe portion to the second pipe portion and providing a first connection flow path communicating with each of the first pipe flow path and the second pipe flow path; and
a working fluid configured to flow through the first pipe flow path, the second pipe flow path, and the first connection flow path, and
wherein each of the first pipe portion and the second pipe portion comprises:
a plurality of contact portions including contact surfaces contacting the display panel; and
a plurality of spaced portions arranged alternately with the plurality of contact portions and spaced apart from the display panel.

12. The display device of claim 11, wherein each of the first pipe portion and the second pipe portion comprises a pulsating heat pipe (PHP).

13. The display device of claim 11, wherein the plurality of contact portions are configured to evaporate at least a portion of the working fluid and the plurality of spaced portions are configured to condense the portion of the working fluid.

14. The display device of claim 11, wherein the first pipe portion and the second pipe portion are configured to circulate the working fluid therethrough.

15. The display device of claim 11, wherein, when viewed from a front, each of the first pipe portion and the second pipe portion has a serpentine shape.

16. The display device of claim 11, wherein the first pipe portion and the second pipe portion are arranged side-by-side.

17. The display device of claim 11, wherein at least a portion of the first connection portion contacts the display panel.

18. The display device of claim 11, wherein the heat dissipation portion further comprises:
a third pipe portion extending in the first direction, providing a third pipe flow path communicating with the second pipe flow path, and spaced apart from the second pipe portion in the second direction; and
a second connection portion connecting the first pipe portion to the third pipe portion and providing a second connection flow path communicating with each of the first pipe flow path and the third pipe flow path.

19. The display device of claim 18, wherein the second connection portion extends in the second direction.

20. The display device of claim 11, wherein the display panel includes a first surface configured to display an image and a second surface opposite to the first surface, and
the heat dissipation portion is on the second surface of the display panel.
